(19) United States
(12) Patent Application Publication
(10) Pub. No.: US 2026/0101596 A1
(43) Pub. Date: Apr. 9, 2026

(54) PHOTOELECTRIC CONVERTER, SOLID-STATE IMAGE SENSOR, AND RANGING SYSTEM

(71) Applicant: SONY SEMICONDUCTOR SOLUTIONS CORPORATION, KANAGAWA (JP)

(72) Inventor: NOBUE MAEKAWA, KANAGAWA (JP)

(21) Appl. No.: 19/109,588

(22) PCT Filed: Sep. 15, 2022
(86) PCT No.: PCT/JP2022/034522

§ 371 Date: Mar. 7, 2025

(51) Int. Cl. H10F 39/00; H10F 39/18

(52) U.S. Cl. CPC H10F 39/80373; H10F 39/182; H10F 39/805

(57) ABSTRACT

A photoelectric converter according to an aspect of the present disclosure includes a semiconductor layer that is a SiGe layer or a Ge layer and a photodiode formed in the semiconductor layer. This solid-state image sensor further includes a transistor and a Si layer. The transistor has a source region and a drain region in the semiconductor layer and has a gate electrode in contact with the semiconductor layer via a gate insulating film. The Si layer is formed at an interface between the semiconductor layer and the gate insulating film.

### TECHNICAL FIELD

The present disclosure relates to a photoelectric converter, a solid-state image sensor, and a ranging system.

### BACKGROUND ART

There has been known a solid-state image sensor having a photoelectric converter formed in a Si layer, a SiGe layer or a Ge layer (See PTLs 1 to 3, for example).

### CITATION LIST

### Patent Literature

PTL 1: Japanese Unexamined Patent Application Publication No. 2010-183095

### SUMMARY OF THE INVENTION

Incidentally, a solid-state image sensor having a photoelectric converter formed in a Si layer has low quantum efficiency Qe in a near-infrared ray region and low sensor sensitivity in the near-infrared ray region. In contrast, in a solid-state image sensor having a photoelectric converter formed in a SiGe layer or a Ge layer, the quantum efficiency Qe in the near-infrared region is high. However, the solid-state image senor having a photoelectric converter formed in a SiGe layer or a Ge layer has a disadvantage that a dark current is large due to a defect on an oxide film interface as compared to the Si layer. Hence, it is desirable to provide a photoelectric converter that makes it possible to reduce the dark current in the SiGe layer or the Ge layer, as well as a solid-state image sensor and a ranging system that include such a photoelectric converter for each pixel.

A photoelectric converter according to a first aspect of the present disclosure includes a semiconductor layer that is a SiGe layer or a Ge layer and a photodiode formed in the semiconductor layer. This solid-state image sensor further includes a transistor and a Si layer. The transistor has a source region and a drain region in the semiconductor layer and has a gate electrode in contact with the semiconductor layer via a gate insulating film. The Si layer is formed at an interface between the semiconductor layer and the gate insulating film.

A photoelectric converter according to a second aspect of the present disclosure includes a semiconductor layer that is a SiGe layer or a Ge layer and a photodiode formed in the semiconductor layer. This solid-stage image sensor further includes a transistor and a Si layer. The transistor has a source region and a drain region in the semiconductor layer and has a gate electrode extending in the semiconductor layer. The Si layer is formed at an interface between the semiconductor layer and the gate electrode.

A solid-state image sensor according to a third aspect of the present disclosure includes a photoelectric converter for each pixel. The photoelectric converter has a semiconductor layer that is a SiGe layer or a Ge layer and a photodiode formed in the semiconductor layer. This solid-state image sensor further includes a transistor and a Si layer. The transistor has a source region and a drain region in the semiconductor layer and has a gate electrode in contact with the semiconductor layer via a gate insulating film. The Si layer is formed at an interface between the semiconductor layer and the gate insulating film.

A solid-state image sensor according to a fourth aspect of the present disclosure includes a photoelectric converter for each pixel. The photoelectric converter has a semiconductor layer that is a SiGe layer or a Ge layer and a photodiode formed in the semiconductor layer. This solid-state image sensor further includes a transistor and a Si layer. The transistor has a source region and a drain region in the semiconductor layer and has a gate electrode extending in the semiconductor layer. The Si layer is formed at an interface between the semiconductor layer and the gate electrode.

A ranging system according to a fifth aspect of the present disclosure includes a photoelectric converter for each pixel. The photoelectric converter has a semiconductor layer that is a SiGe layer or a Ge layer and a photodiode formed in the semiconductor layer. This solid-state image sensor further includes a transistor and a Si layer. The transistor has a source region and a drain region in the semiconductor layer and has a gate electrode in contact with the semiconductor layer via a gate insulating film. The Si layer is formed at an interface between the semiconductor layer and the gate insulating film.

A ranging system according to a sixth aspect of the present disclosure includes a photoelectric converter for each pixel. The photoelectric converter has a semiconductor layer that is a SiGe layer or a Ge layer and a photodiode formed in the semiconductor layer. This solid-state image sensor further includes a transistor and a Si layer. The transistor has a source region and a drain region in the semiconductor layer and has a gate electrode extending in the semiconductor layer. The Si layer is formed at an interface between the semiconductor layer and the gate electrode.

### BRIEF DESCRIPTION OF DRAWING

FIG. 1 is a diagram illustrating an example of a circuit configuration of a pixel including a photoelectric converter according to an embodiment of the present disclosure.

FIG. 2 is a diagram illustrating an example of a cross-sectional configuration of the photoelectric converter of FIG. 1.

FIG. 3A is a diagram explaining a manufacturing process of the photoelectric converter of FIG. 2.

FIG. 3B is a diagram explaining a manufacturing process following FIG. 3A.

FIG. 3C is a diagram explaining a manufacturing process following FIG. 3B.

FIG. 3D is a diagram explaining a manufacturing process following FIG. 3C.

FIG. 3E is a diagram explaining a manufacturing process following FIG. 3D.

FIG. 3F is A diagram explaining a manufacturing process following FIG. 3E.

FIG. 3G is a diagram explaining a manufacturing process following FIG. 3F.

FIG. 3H is a diagram explaining a manufacturing process following FIG. 3G.

FIG. 3I is a diagram explaining a manufacturing process following FIG. 3H.

FIG. 4 is a diagram illustrating a modification example of a cross-sectional configuration of the photoelectric converter of FIG. 2.

FIG. 5 is a diagram illustrating a modification example of the cross-sectional configuration of the photoelectric converter of FIG. 2.

FIG. 6 is a diagram illustrating a modification example of the cross-sectional configuration of the photoelectric converter of FIG. 4.

FIG. 7 is a diagram illustrating a modification example of the cross-sectional configuration of the photoelectric converter of FIG. 2.

FIG. 8A is a diagram explaining a manufacturing process of the photoelectric converter of FIG. 2.

FIG. 8B is a diagram explaining a manufacturing process following FIG. 8A.

FIG. 8C is a diagram explaining a manufacturing process following FIG. 8B.

FIG. 8D is a diagram explaining a manufacturing process following FIG. 8C.

FIG. 8E is a diagram explaining a manufacturing process following FIG. 8D.

FIG. 8F is A diagram explaining a manufacturing process following FIG. 8E.

FIG. 8G is a diagram explaining a manufacturing process following FIG. 8F.

FIG. 8H is a diagram explaining a manufacturing process following FIG. 8G.

FIG. 8I is a diagram explaining a manufacturing process following FIG. 8H.

FIG. 9 is a diagram illustrating a modification example of the cross-sectional configuration of the photoelectric converter of FIG. 2.

FIG. 10 is diagram illustrating a modification example of the cross-sectional configuration of the photoelectric converter of FIG. 2.

FIG. 11 is a diagram illustrating an application example when the photoelectric converters according to the above-described embodiment and the modification examples thereof are applied to a ranging apparatus.

FIG. 12 is a diagram illustrating a schematic configuration example of a light detection unit of FIG. 11.

FIG. 13 is a block diagram depicting an example of schematic configuration of a vehicle control system.

FIG. 14 is a diagram of assistance in explaining an example of installation positions of an outside-vehicle information detecting section and an imaging section.

### MODES FOR CARRYING OUT THE INVENTION

In the following, a description will be given of embodiments of the present disclosure with reference to the drawings.

### 1. Embodiment

### Configuration

A description will be given of a photoelectric converter according to an embodiment of the present disclosure. FIG. 1 illustrates an example of a circuit configuration of a pixel including a photoelectric converter 10 according to an embodiment of the present disclosure and a readout circuit 20 that reads out a signal from the photoelectric converter 10. A solid-state image sensor including a plurality of pixels in FIG. 1 is, for example, a back-illuminated image sensor including a CMOS (Complementary Metal Oxide Semiconductor) image sensor, and the like. The solid-state image sensor captures an image by receiving light from a subject and photoelectrically converting the light to generate a pixel signal. The solid-state image sensor outputs a pixel signal according to input light. It is to be noted that the present disclosure is not limited to application to a CMOS image sensor. In addition, at least some of the plurality of pixels included in the solid-state image sensor include the photoelectric converter 10 according to an embodiment of the present disclosure and the readout circuit 20 that reads out a signal from the photoelectric converter 10.

The photoelectric converter 10 includes, for example, a photodiode PD, a transfer transistor TR electrically coupled to the photodiode PD, and a floating diffusion FD that temporarily holds electric charges output from the photodiode PD via the transfer transistor TR.

The photodiode PD performs photoelectric conversion to generate electric charges according to an amount of light received. A cathode of the photodiode PD is electrically coupled to a source of the transfer transistor TR, and an anode of the photodiode PD is electrically coupled to a reference potential line (for example, a ground GND). A drain of the transfer transistor TR is electrically coupled to the floating diffusion FD, and a gate of the transfer transistor TR is electrically coupled to a pixel drive line. The transfer transistor TR is, for example, a NMOS (Metal Oxide Semiconductor) transistor.

The readout circuit 20 includes, for example, a reset transistor RST, an amplification transistor AMP, and a selection transistor SEL.

A source of the reset transistor RST (an input end of the readout circuit 20) is electrically coupled to the floating diffusion FD, and a drain of the reset transistor RST is electrically coupled to a drain of a power-supply line VDD and a drain of the amplification transistor AMP. A gate of the reset transistor RST is electrically coupled to the pixel drive line. A source of the amplification transistor AMP is electrically coupled to a drain of the selection transistor SEL, and a gate of the amplification transistor AMP is electrically coupled to the floating diffusion FD. A source of the selection transistor SEL (output end of the readout circuit 20) is electrically coupled to a vertical signal line VSL, and a gate of the selection transistor SEL is electrically coupled to the pixel drive line. When the transistor TR enters ON-state, the transistor TR transfers the electric charges of the photodiode PD to the floating diffusion FD.

The reset transistor RST resets a potential of the floating diffusion FD to a predetermined potential. When the reset transistor RST enters ON-state, the reset transistor RST resets the potential of the floating diffusion FD to a potential of the power-supply line VDD. The selection transistor SEL controls output timing of a pixel signal from the readout circuit 20.

The amplification transistor AMP generates, as a pixel signal, a signal with a voltage corresponding to a level of electric charges held in the floating diffusion FD. The amplification transistor AMP includes an amplifier of a source follower type, and outputs a pixel signal with a voltage corresponding to a level of electric charges generated in the photodiode PD. When the selection transistor SEL enters ON-state, the amplification transistor AMP amplifies the potential of the floating diffusion FD and outputs a voltage corresponding to the potential to outside of the pixel via the vertical signal line VSL.

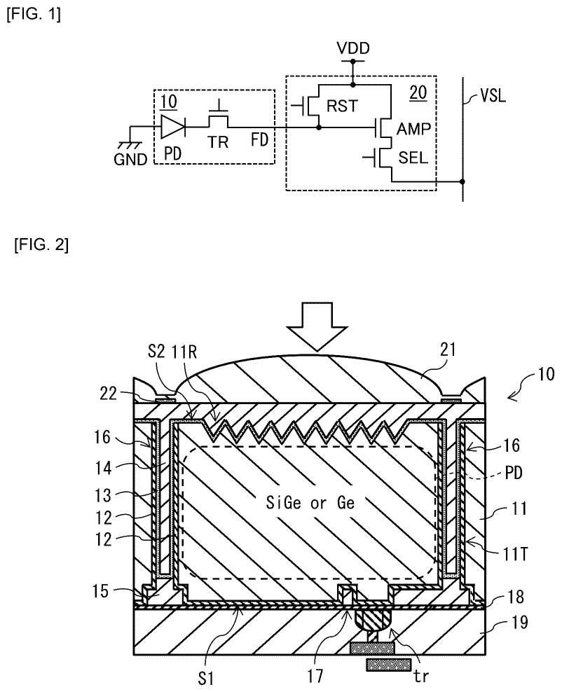

FIG. 2 illustrates an example of a cross-sectional configuration of the photoelectric converter 10. The photoelectric converter 10 has a configuration in which the photodiode PD is formed in the semiconductor substrate 11. The photoelectric converter 10 has a transistor tr on a top surface (lower side of plane of paper) of the semiconductor substrate 11, and has a light receiving lens 21 and a light shielding layer 22 on a rear surface (upper side of the plane of paper) of the semiconductor substrate 11. The transistor tr is an NMOS transistor, for example. The light receiving lens 21 is provided at a location facing the photodiode PD in the semiconductor substrate 11, and guides light (entering light) that enters from the outside to the photodiode PD. The light shielding layer 22 includes, for example, a metal material, and is provided to surround a periphery of the light receiving lens 21. The light shielding layer 22 has a function to reduce light entering from adjacent pixels.

The semiconductor substrate 11 is a GeSi substrate (GeSi layer) or a Ge substrate (Ge layer), for example. The photodiode PD is formed in the semiconductor substrate 11 (for example, the GeSi substrate (GeSi layer) or the Ge substrate (Ge layer)). The source region and the drain region of the transistor tr are formed in the semiconductor substrate 11 (for example, the GeSi substrate (GeSi layer) or the Ge substrate (Ge layer)). As illustrated in FIG. 2, for example, the gate of the transistor tr is formed on a top surface S1 of the semiconductor substrate 11 via a gate insulating film 18 and a cap Si layer 12. The cap Si layer 12 is formed at an interface between the top surface S1 of the semiconductor substrate 11 and the gate insulating film 18.

The cap Si layer 12 is formed in contact with the top surface S1 of the semiconductor substrate 11, covering the entire top surface S1 of the semiconductor substrate 11. The cap Si layer 12 has a thickness that is equal to or less than a critical film thickness, for example. The gate insulating film 18 is formed in contact with the cap Si layer 12 and a filling insulating layer 15 to be described below. The gate insulating film 18 includes SiO₂ and SiON, for example. The cap Si layer 12 includes Si.

As illustrated in FIG. 2, for example, in the semiconductor substrate 11 is formed an isolation trench 17 that isolates the transistor tr. The isolation trench 17 is formed to surround the transistor tr in a planar view. The cap Si layer 12 and the filling insulating layer 15 are provided in the isolation trench 17, the cap Si layer 12 being in contact with a bottom surface and a side surface (that is, a portion of the top surface S1 of the semiconductor substrate 11) of the isolation trench 17, and the filling insulating layer 15 filling the isolation trench 17. The cap Si layer 12 is formed at an interface between the bottom surface and the side surface of the isolation trench 17 and the filling insulating layer 15. The filling insulating layer 15 includes SiO₂, for example.

Furthermore, as illustrated in FIG. 2, for example, a pixel separation structure 16 is formed in the semiconductor substrate 11, the pixel separation structure insulating and separating pixels that are adjacent to each other. In the semiconductor substrate 11, the pixel separation structure 16 is formed to surround the photodiode PD. As illustrated in FIG. 2, for example, the pixel separation structure 16 has an ST1 (Shallow Trench Isolation) structure at a location closer to the top surface of the semiconductor substrate 11, and has a filling structure connected with the STI structure at a location closer to a middle and the rear surface S2 of the semiconductor substrate 11.

As illustrated in FIG. 2, for example, the pixel separation structure 16 has a through hole 11T penetrating the semiconductor substrate 11. Within the through hole 11T are provided the cap Si layer 12 in contact with an inner surface of the through hole 11T (i.e., a portion of a surface of the semiconductor substrate 11), an oxide film 13 in contact with and covering a surface of the cap Si layer 12, and filling insulating layers 14 and 15 filling the through hole 11T. The cap Si layer 12 is formed at an interface between the inner surface of the through hole 11T and the filling insulating layers 14 and 15.

The oxide film 13 covers the cap Si layer 12 in the through hole 11T and the rear surface S2 of the semiconductor substrate 11. The oxide film 13 includes a silicon oxide film (SiOx), for example. The filling insulating layer 14 is provided not only to fill inside of the through hole 11T, but also to cover the oxide film 13 that is in contact with the rear surface S2 of the semiconductor substrate 11. The filling insulating layer 14 has a flat surface on which the light receiving lens 21 is to be formed. The filling insulating layer 14 includes, for example, Poly-Si, aluminum (Al), and tungsten (W) in the through hole 11T, and includes, for example, SiO2 at a location between the photodiode PD and the light receiving lens 21.

As illustrated in FIG. 2, for example, an anti-reflection structure 11R is provided on the rear surface S2 of the semiconductor layer 11. The anti-reflection structure 11R has, for example, an uneven shape formed on the rear surface S2 of the semiconductor substrate 11.

### Manufacturing Method

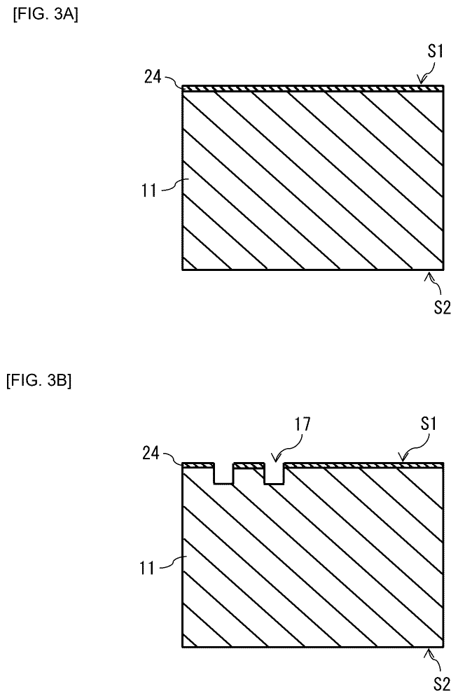

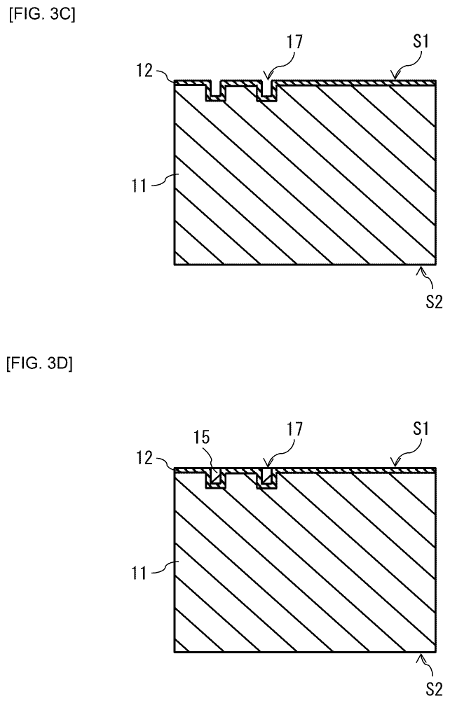

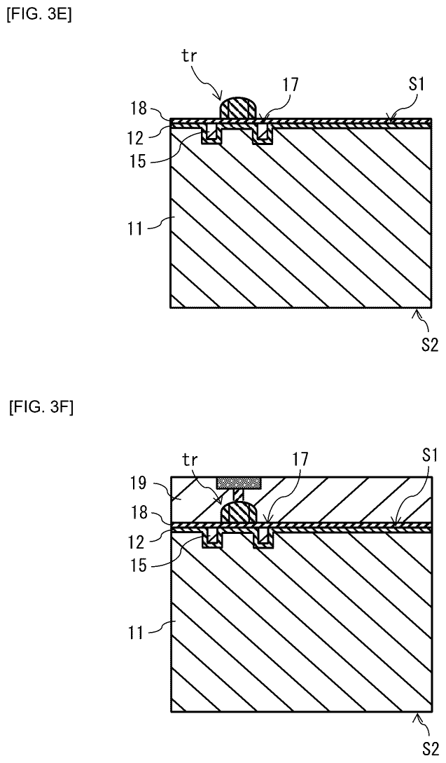

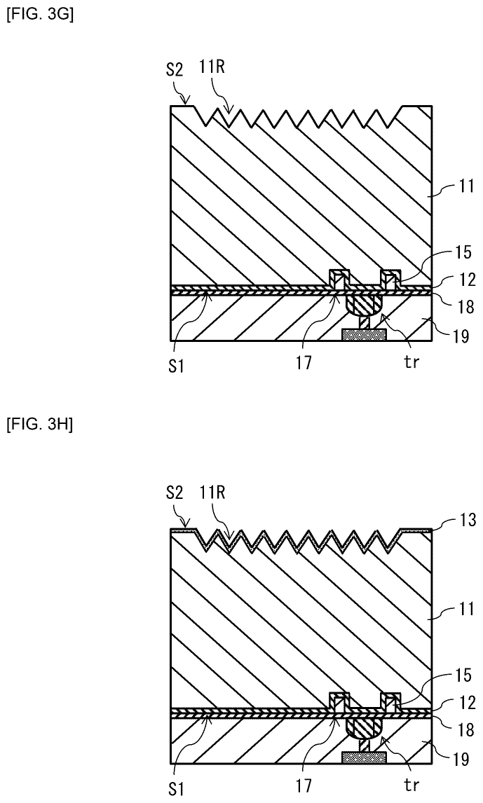

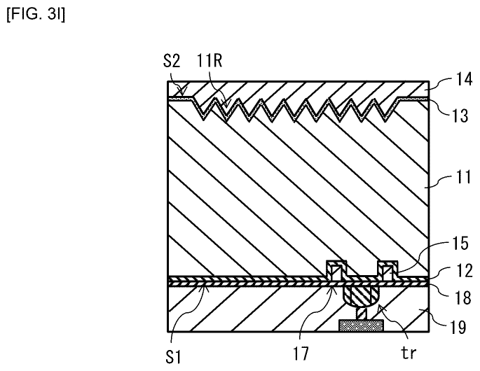

Next, a description will be given of a method of manufacturing the photoelectric converter 10 in the present embodiment. FIG. 3A to FIG. 3J illustrate an example of manufacturing processes of the photoelectric converter 10 according to this present embodiment.

First, form a SiN layer 24 on the top surface S1 of the semiconductor substrate 11 (FIG. 3A). Next, form openings at predetermined locations on the SiN layer 24, for example, by means of a photolithographic approach. Subsequently, selectively etch the semiconductor substrate 11 with the SiN layer 24 a mask, for example, by means of a dry etching method. As a result, the isolation trench 17 having a predetermined depth with respect to the semiconductor substrate 11 is to be formed (FIG. 3B).

Next, form the cap Si layer 12 to cover the entire top surface S1 of the semiconductor substrate 11, including an inner surface of the isolation trench 17. The cap Si layer 12 is to be formed, for example, by means of the Si epitaxial method. As a result, the cap Si layer 12 is to be formed in contact with the entire top surface S1 of the semiconductor substrate 11 including the inner surface of the isolation trench 17 (FIG. 3C).

Next, form the filling insulating layer 15 that fills the isolation trench 17 (FIG. 3D). Subsequently, after forming the gate insulating layer 18 covering the cap Si layer 12 and the filling insulating layer 15, form a gate electrode. As a result, the transistor tr having the source region and the drain region is to be formed on the GeSi layer or the Ge layer (FIG. 3E). Thereafter, not only form wiring coupled to the gate electrode, but also form an insulating layer 19 in which the wiring is buried (FIG. 3F).

Next, after forming the anti-reflection structure 11R on the rear surface S2 of the semiconductor substrate 11 (FIG. 3G), form the oxide film 13 over the entire rear surface S2 of the semiconductor substrate 11 (FIG. 3H). Thereafter, form the filling insulating layer 14 to cover the rear surface S2 of the semiconductor substrate 11 (FIG. 3I). Lastly, form the light receiving lens 21 on the filling insulating layer 14. The photoelectric converter 10 according to the present embodiment is to be manufactured in this manner.

### Effects

Hereinafter, a description will be given of effects of the photoelectric converter 10 according to the present embodiment.

In the present embodiment, the photodiode PD and the source region and the drain region of the transistor tr are formed in the semiconductor substrate 11 (for example, the GeSi substrate (GeSi layer) or the Ge substrate (Ge layer)). Then, the cap Si layer 12 is formed in contact with a part that is an interface of the semiconductor substrate 11 (specifically, the top surface S1 and the inner surface of the through hole 11T). This makes it possible to suppress generation of a dark current at the interface between the gate insulating layer 18 and the top surface S1 of the semiconductor substrate 11 or an interface between the pixel separation structure 16 (oxide film 13) and the semiconductor substrate 11. Therefore, it is possible to realize the photoelectric converter 10 having a small dark current.

In the present embodiment, the cap Si layer 12 has the thickness that is equal to or less than the critical film thickness. This allows the photodiode PD including GeSi or Ge to have a wider area. In addition, in a case where the cap Si layer is formed by means of epitaxial growth, it is possible to shorten manufacturing time.

In the present embodiment, the cap Si layer 12 is also formed at an interface between the inner surface of the isolation trench 17 and the filling insulating layer 15. This makes it possible to suppress the generation of the dark current at the interface between the inner surface of the isolation trench 17 and the filling insulating layer 15. Therefore, it is possible to realize the photoelectric converter 10 having a small dark current.

In the present embodiment, the cap SI layer 12 is also formed at an interface between the inner surface of the through hole 11T and the filling insulating layer 15 and the oxide film 13. This makes it possible suppress the generation of the dark current at the interface between the inner surface of the through hole 11T and the filling insulating layer 15 and the oxide film 13. Therefore, it is possible to realize the photoelectric converter 10 having a small dark current.

### 2. Modification Examples

Next, a description will be given of modification examples of the photoelectric converter 10 according to the embodiment described above. In the following, common components are denoted by common reference numerals, and a description thereof will be omitted where appropriate.

### Modification Example A

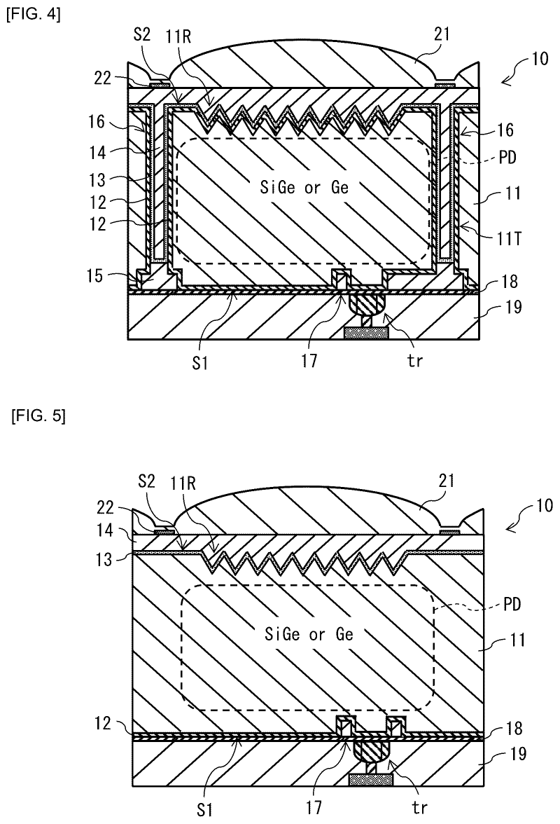

In the present embodiment described above, the cap Si layer 12 may cover the top surface S1 of the semiconductor substrate 11 as well as the rear surface S2 (anti-reflection structure 11R, light entering surface) of the semiconductor substrate 11, as illustrated in FIG. 4, for example. At this time, the cap Si layer 12 is in contact with the rear surface S2 (anti-reflection structure 11R) of the semiconductor substrate 11, and is formed at an interface between the oxide film 13 and the rear surface S2 (anti-reflection structure 11R) of the semiconductor substrate 11. In such a case, it is possible to suppress the generation of the dark current at the interface between the oxide film 13 and the rear surface S2 of the semiconductor substrate S2. Therefore, it is possible to realize the photoelectric converter 10 having a small dark current.

### Modification Example B

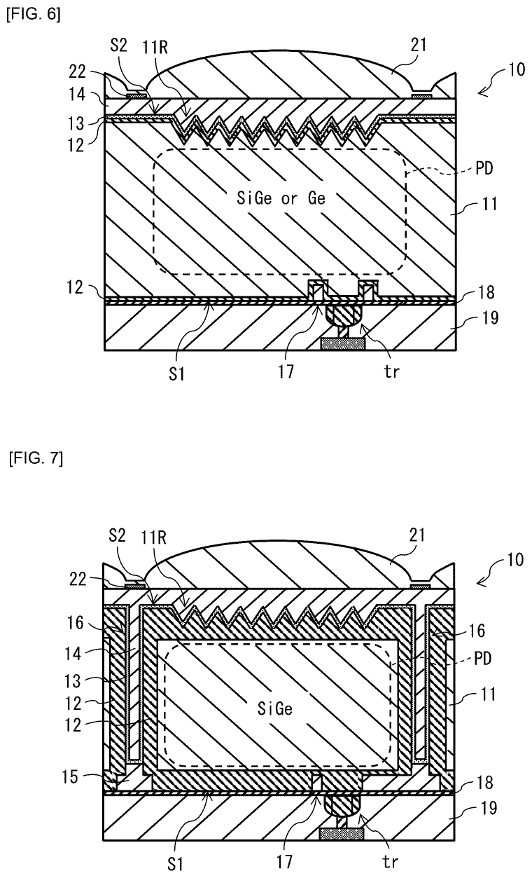

In the above-described embodiment and the modification example thereof, the pixel separation structure 16 may be omitted, for example, as illustrated in FIGS. 5 and 6. In this case, because there is no interface between the pixel separation structure 16 (oxide film 13) and semiconductor substrate 11 in the first place, no dark current is generated at the interface between the pixel separation structure 16 (oxide film 13) and the semiconductor substrate 11.

### Modification Example C

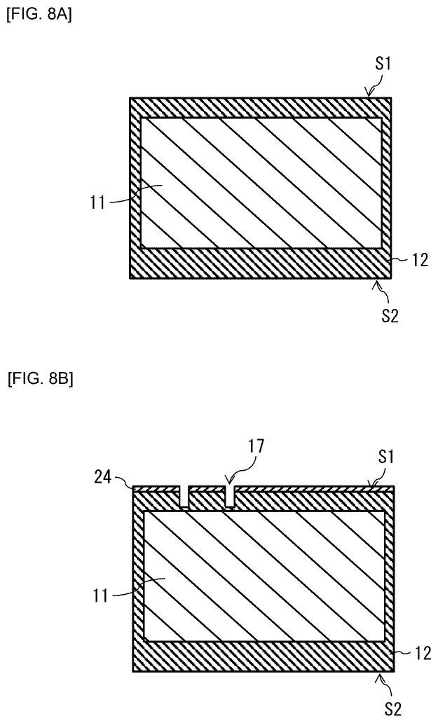

In the above-described modification example A, the semiconductor substrate 11 may be a Si substrate. At this time, as illustrated in FIG. 7, for example, the layer (GeSi layer) of the semiconductor substrate 11 where the photodiode PD and the source region and the drain region of the transistor tr are formed may be formed by implantation of Ge into the Si substrate.

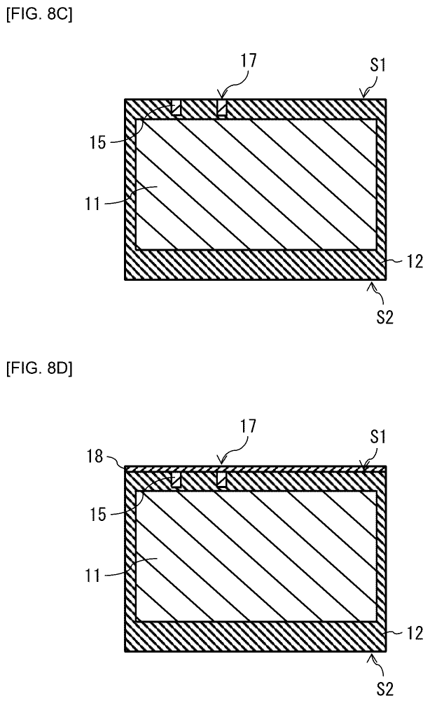

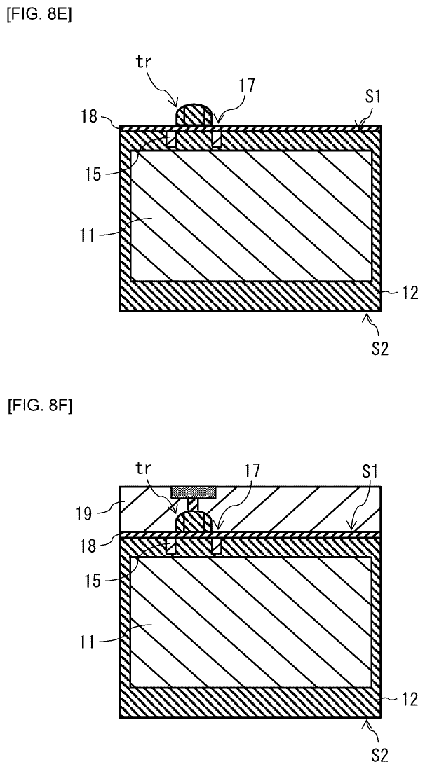

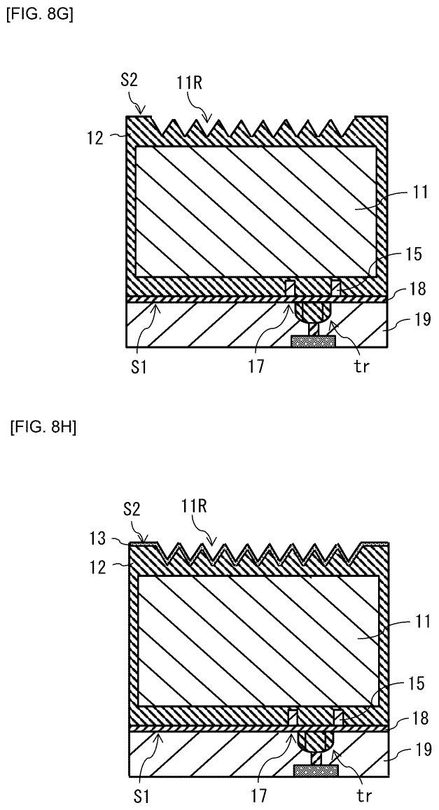

Next, a description will be given of a method of manufacturing the photoelectric converter 10 in this modification example. FIGS. 8A to 8I represent an example of manufacturing processes of the photoelectric converter 10 according to this modification example.

First, implant Ge into a predetermined location of the semiconductor substrate 11 that is the Si substrate. As a result, a GeSi layer into which Ge is implanted and the cap Si layer 12 into which no Ge is implanted are to be formed in the semiconductor substrate 11 (FIG. 8A). Next, after forming the SiN layer 24 on the top surface S1 of the semiconductor substrate 11, form openings at predetermined locations of the SiN layer 24, for example, by means of the photolithographic approach. Subsequently, selectively etch the semiconductor substrate 11 with the SiN layer 24 as a mask, for example, by means of the dry etching method. As a result, the isolation trench 17 having the predetermined depth with respect to the semiconductor substrate 11 is to be formed (FIG. 8B).

Next, form the filling insulating layer 15 that fills the isolation trench 17 (FIG. 8C). Subsequently, after forming the gate insulating layer 18 covering the cap Si layer 12 and the filling insulating layer 15 (FIG. 8D), form a gate electrode. As a result, the transistor tr having the source region and the drain region is to be formed on the GeSi layer (FIG. 8E). Thereafter, not only form the wiring coupled to the gate electrode, but also form the insulating layer 19 in which the wiring is buried (FIG. 8F).

Next, after forming the anti-reflection structure 11R on the rear surface S2 of the semiconductor substrate 11 (FIG. 8G), form the oxide film 13 over the entire rear surface S2 of the semiconductor substrate 11 (FIG. 8H). Thereafter, form the filling insulating layer 14 to cover the rear surface S2 of the semiconductor substrate 11 (FIG. 8I). Lastly, form the light receiving lens 21 on the filling insulating layer 14. The photoelectric converter 10 according to this modification example is to be manufactured in this manner.

In this modification example, the photodiode PD and the source region and the drain region of the transistor tr are formed in the GeSi region of the semiconductor substrate 11. Then, the cap Si layer 12 is formed at a part that is the interface of the semiconductor substrate 11 (specifically, the top surface S1 of the semiconductor substrate 11 and the inner surface of the through hole 11T). This makes it possible to suppress the generation of the dark current at the interface between the gate insulating layer 18 and the top surface S1 of the semiconductor substrate 11 or the interface between the pixel separation structure 16 (oxide film 13) and the semiconductor substrate 11. Therefore, it is possible to realize the photoelectric converter 10 having a small dark current.

### Modification Example D

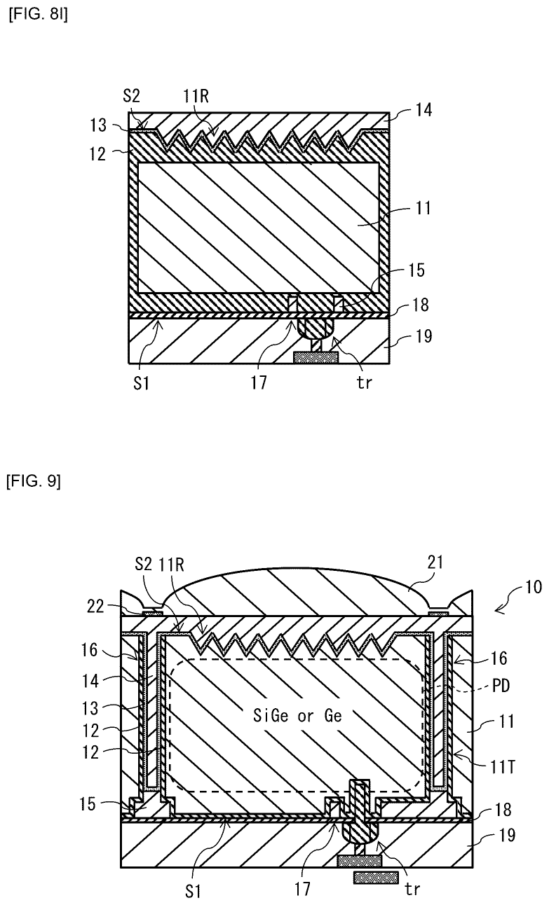

In the above-described embodiment and the modification examples thereof, the gate electrode of the transistor tr may be formed to extend in the semiconductor substrate 11, as illustrated in FIG. 9, for example. In this modification example, the transistor tr may be, for example, the transfer transistor TR. At this time, the cap Si layer 12 is formed at an interface between the gate electrode of the transistor tr and the semiconductor substrate 11. The cap Si layer 12 has the thickness that is equal to or less than the critical film thickness, for example. This makes it possible to suppress the generation of the dark current at the interface between the gate electrode of the transistor tr and the semiconductor substrate 11. Therefore, it is possible to realize the photoelectric converter 10 having a small dark current. It is to be noted that in this modification example, the cap Si layer 12 may cover the top surface S1 of the semiconductor substrate 11 as well as the rear surface S2 (anti-reflection structure 11R, light entering surface) of the semiconductor substrate 11, as illustrated in FIG. 4, for example. In such a case, it is possible to suppress the generation of the dark current at the interface between the oxide film 13 and the rear surface S2 of the semiconductor substrate S2. Therefore, it is possible to realize the photoelectric converter 10 having a small dark current.

### Modification Example E

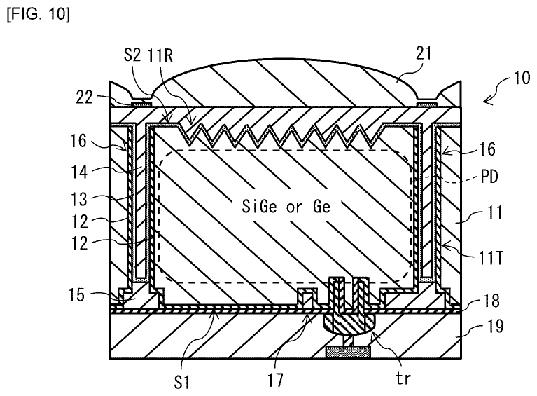

In the above-described embodiment and the modification examples thereof, as illustrated in FIG. 10, for example, the gate electrode of the transistor tr may include a pair of electrodes (so-called fin structure) that holds a portion of the semiconductor substrate 11 in between from a direction orthogonal to a thickness direction of the semiconductor substrate 11. At this time, the cap Si layer 12 is formed at an interface between the gate electrode of the transistor tr and the semiconductor substrate 11. The cap Si layer 12 has the thickness that is equal to or less than the critical film thickness, for example. This makes it possible to suppress the generation of the dark current at the interface between the gate electrode of the transistor tr and the semiconductor substrate 11. Therefore, it is possible to realize the photoelectric converter 10 having a small dark current. It is to be noted that in this modification example, the cap Si layer 12 may cover the top surface S1 of the semiconductor substrate 11 as well as the rear surface S2 (anti-reflection structure 11R, light entering surface) of the semiconductor substrate 11, as illustrated in FIG. 4, for example. In such a case, it is possible to suppress the generation of the dark current at the interface between the oxide film 13 and the rear surface S2 of the semiconductor substrate S2. Therefore, it is possible to realize the photoelectric converter 10 having a small dark current.

### 3. Application Examples

Next, a description will be given of application examples of the photoelectric converter 10 according to the above-described embodiment and the modification examples thereof. In the following, common components are denoted by common reference numerals, and a description thereof will be omitted where appropriate.

### Application Example A

FIG. 11 illustrates a schematic configuration example of a ranging system 100 that uses the photoelectric converter 10 according to the above-described embodiment and modification examples thereof. The ranging system 100 is a ToF (Time Of Flight) sensor, and emits light and detects reflected light reflected by a detection target. The ranging system 100 includes, for example, a light emitting unit 110, an optical system 120, a light detection unit 130, a controller 140, and a communication unit 150, as illustrated in FIG. 11.

The light emitting unit 110 emits a light pulse La (signal light) toward the detection target, on the basis of an instruction from the controller 140. The light emitting unit 110 emits the light pulse La by performing a light emission operation on the basis of the instruction from the controller 140. The light emission operation repeats light emission and non-emission alternately. The light emitting unit 110 has, for example, a light source that emits infrared light. This light source is configured by using, for example, a laser light source or an LED (Light Emitting Diode), and the like.

The optical system 120 includes a lens that causes an image to be formed on a light receiving surface of the light detection unit 130. Light pulses (reflected light pulses Lb) emitted from the light emitting unit 110 and reflected by the detection target are to enter this optical system 120.

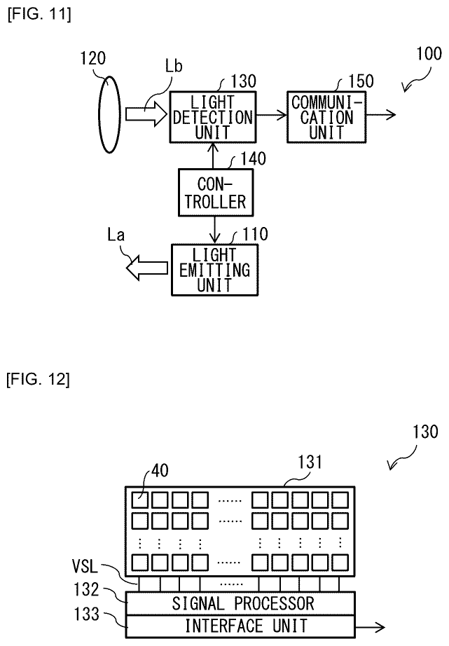

The light detection unit 130 detects the reflected light pulses Lb on the basis of the instruction from the controller 140. The light detection unit 130 generates distance image data on the basis of a detection result, and outputs the generated distance image data to the outside via the communication unit 150. As illustrated in FIG. 12, the light detection unit 130 includes, for example, a pixel array unit 131 in which the photoelectric converter 10 according to the above-described embodiment and the modification examples thereof is provided for each of pixels 40, a signal processor 132, and an interface unit 133.

The pixel array unit 131 has a plurality of the pixels 40 that performs photoelectric conversion. The plurality of pixels 40 is disposed in a matrix in an effective pixel region. In the pixel array unit 131, the vertical signal line VSL is wired in a row direction for every pixel row. The vertical signal line VSL is wiring for reading out signals from the pixels 40. One end of the vertical signal line VSL is coupled to the signal processor 132.

The signal processor 132 has, for example, a readout circuit for each pixel row of the pixel array unit 131. The readout circuit performs predetermined signal processing on a signal to be output from a corresponding pixel 40 via the vertical signal line VSL. In addition, the readout circuit temporarily holds image data after signal processing. The signal processor 132 outputs image data from a plurality of the readout circuits to the interface unit 133 in sequence, according to control by the controller 140. The interface unit 133 sequentially outputs a plurality of pieces of image data input from the signal processor 132 to the communication unit 150. In this manner, the interface unit 133 outputs the plurality of pieces of image data acquired by the pixel array unit 131 to the communication unit 150 as image data. The controller 140 supplies a control signal to the light emitting unit 110 and the light detection unit 130, and controls these operations to thereby control operations of the ranging system 100.

In this application example, the photoelectric converter 10 according to the above-described embodiment and the modification examples thereof is provided in each of the pixels 40. Alternatively, in this application example, the photoelectric converter 10 according to the above-described embodiment and the modification examples thereof is provided in at least some pixels 40 of the plurality of pixels 40. This makes it possible to provide a ranging system with low noise and high precision.

### Application Example B

A technique according to the present disclosure is applicable to variety of products. For example, the technique according to the present disclosure may be realized as a device to be mounted on any type of mobile object including an automobile, an electric vehicle, a hybrid electric vehicle, a motorcycle, a bicycle, a personal mobility, an airplane, a drone, a ship, a robot, a construction machine, or an agricultural machine (tractor).

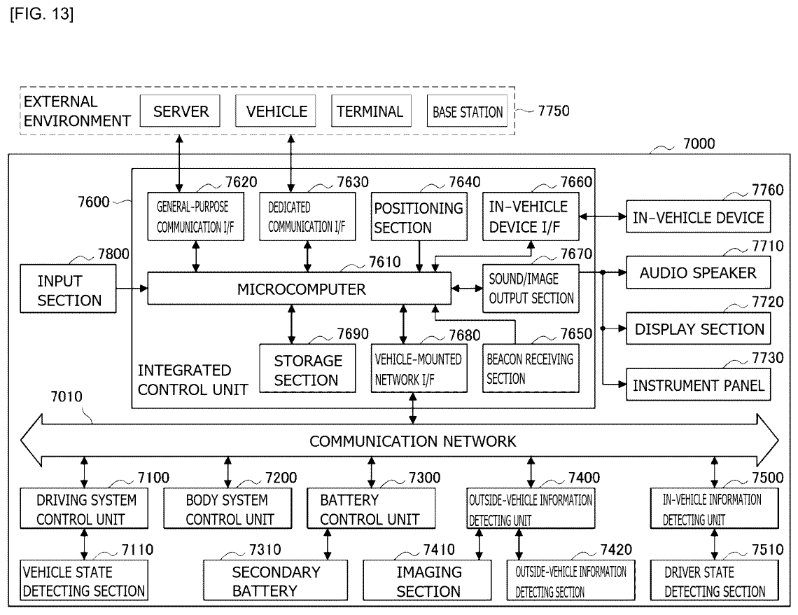

FIG. 13 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 13, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 13 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

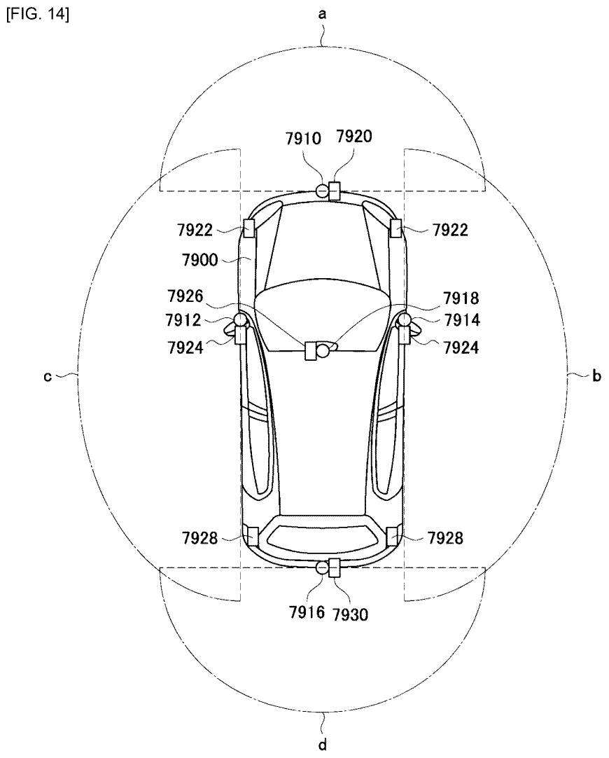

FIG. 14 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 14 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 13, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 13, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 13 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

It is to be noted that it is possible to implement a computer program for realizing each function of the above-described ranging system 100 in any controller, and the like. It is also possible to provide a computer-readable recording medium in which such a computer program is stored. The recording medium is, for example, a magnetic disk, an optical disk, a magneto-optical disk, a flash memory, and the like. In addition, the above-described computer program may be distributed, for example, via a network, without using a recording medium.

In the vehicle control system 7000 described above, it is possible to use the above-described ranging system 100, for example, as a light source steering unit of a LIDAR as an environmental sensor. It is also possible to perform image recognition in the imaging unit by an optical computing unit that uses the above-described ranging system 100. In a case where the above-described ranging system 100 is used as a projection device with high efficiency and high brightness, it is possible to project lines or characters on the ground. Specifically, it is possible to display lines for those outside a vehicle to know where the vehicle will pass when the vehicle backs up, or display a crosswalk with light in a case where the vehicle gives way to pedestrians.

In addition, at least some of the components of the above-described ranging system 100 may be realized in a module (for example, an integrated circuit module including one die) for the integrated control unit 7600 illustrated in FIG. 13. Alternatively, the above-described ranging system 100 may be realized by a plurality of control units of the vehicle control system 7000 illustrated in FIG. 31.

The present disclosure has been described above with reference to the embodiments and the modification examples. However, the present disclosure is not limited to the above-described embodiment and the like, and is modifiable in a variety of ways. It is to be noted that effects described herein are merely exemplary. The effects of the present disclosure are not necessarily limited to the effects described herein. The present disclosure may have any effect other than the effects described herein.

In addition, for example, the present disclosure may have the following configurations:
(1)

A photoelectric converter including:
a semiconductor layer that is a SiGe layer or a Ge layer;
a photodiode formed in the semiconductor layer;
a transistor having a source region and a drain region in the semiconductor layer and having a gate electrode in contact with the semiconductor layer via a gate insulating film; and
a Si layer formed at an interface between the semiconductor layer and the gate insulating film.
(2)

The photoelectric converter according to (1), in which
the Si layer has a thickness equal to or less than a critical film thickness.
(3)

The photoelectric converter according to (1) or (2), in which the semiconductor layer has a light entering surface and an oxide film covering the light entering surface, and
the Si layer is also formed at an interface between the light entering surface and the oxide film.
(4)

The photoelectric converter according to any one of (1) to (3), in which
the semiconductor layer has an isolation trench formed to surround the transistor,
the photoelectric converter has a first filling insulating layer that fills the isolation trench, and
the Si layer is formed at an interface between an inner surface of the isolation trench and the first filling insulating layer.
(5)

The photoelectric converter according to any one of (1) to (4), in which
the semiconductor layer has a through hole formed to surround the photodiode,
the photoelectric converter has a second filling insulating layer that fills the through hole, and
the Si layer is also formed at an interface between an inner surface of the through hole and the second filling insulating layer.
(6)

A photoelectric converter including:
a semiconductor layer that is a SiGe layer or a Ge layer;
a photodiode formed in the semiconductor layer;
a transistor having a source region and a drain region in the semiconductor layer and having a gate electrode extending in the semiconductor layer; and
a Si layer formed at an interface between the semiconductor layer and the gate electrode.
(7)

The photoelectric converter according to (6), in which
the Si layer has a thickness equal to or less than a critical film thickness.
(8)

The photoelectric converter according to (6) or (7), in which
the semiconductor layer has a light entering surface and an oxide film covering the light entering surface, and
the Si layer is also formed at an interface between the light entering surface and the oxide film.
(9)

The photoelectric converter according to any one of (6) to (8), in which the semiconductor layer has an isolation trench formed to surround the transistor,
the photoelectric converter has a first filling insulating layer that fills the isolation trench, and the Si layer is formed at an interface between an inner surface of the isolation trench and the first filling insulating layer.
(10)

The photoelectric converter according to any one of (6) to (9), in which
the semiconductor layer has a through hole formed to surround the photodiode,
the photoelectric converter has a second filling insulating layer that fills the through hole, and
the Si layer is formed at an interface between an inner surface of the through hole and the second filling insulating layer.
(11)

A solid-state image sensor including:
a photoelectric converter for each pixel, in which
the photoelectric converter has:
a semiconductor layer that is a SiGe layer or a Ge layer;
a photodiode formed in the semiconductor layer;
a transistor having a source region and a drain region in the semiconductor layer and having a gate electrode in contact with the semiconductor layer via a gate insulating film; and
a Si layer formed at an interface between the semiconductor layer and the gate insulating film.
(12)

A solid-state image sensor including:
a photoelectric converter for each pixel, in which
the photoelectric converter has:
a semiconductor layer that is a SiGe layer or a Ge layer;
a photodiode formed in the semiconductor layer;
a transistor having a source region and a drain region in the semiconductor layer and having a gate electrode extending in the semiconductor layer; and
a Si layer formed at an interface between the semiconductor layer and the gate electrode.
(13)

A ranging system including:
a photoelectric converter for each pixel, in which
the photoelectric converter has:
a semiconductor layer that is a SiGe layer or a Ge layer;
a photodiode formed in the semiconductor layer;
a transistor having a source region and a drain region in the semiconductor layer and having a gate electrode in contact with the semiconductor layer via a gate insulating film; and
a Si layer formed at an interface between the semiconductor layer and the gate insulating film.
(14)

A ranging system including:
a photoelectric converter for each pixel, in which
the photoelectric converter has:
a semiconductor layer that is a SiGe layer or a Ge layer;
a photodiode formed in the semiconductor layer;
a transistor having a source region and a drain region in the semiconductor layer and having a gate electrode extending in the semiconductor layer; and
a Si layer formed at an interface between the semiconductor layer and the gate electrode.

In a photoelectric converter according to a first aspect of the present disclosure, a photodiode and a source region and a drain region of a transistor are formed in a semiconductor layer that is a SiGe layer or a Ge layer. Then, a Si layer is formed on a part that is an interface of the semiconductor layer (specifically, an interface between the semiconductor layer and a gate insulating film). This makes it possible to suppress generation of a dark current at the part that is the interface of the semiconductor layer (specifically, the interface between the semiconductor layer and the gate insulating layer). Therefore, it is possible to realize a photoelectric converter having a small dark current.

In a photoelectric converter according to a second aspect of the present disclosure, a photodiode and a source region and a drain region of a transistor are formed in a semiconductor layer that is a SiGe layer or a Ge layer. Then, a Si layer is formed on a part that is an interface of the semiconductor layer (specifically, an interface between the semiconductor layer and a gate electrode). This makes it possible to suppress generation of a dark current at the part that is the interface of the semiconductor layer (specifically, the interface between the semiconductor layer and the gate electrode). Therefore, it is possible to realize a photoelectric converter having a small dark current.

In a solid-state image sensor according to a third aspect of the present disclosure, a photodiode and a source region and a drain region of a transistor are formed in a semiconductor layer that is a SiGe layer or a Ge layer. Then, a Si layer is formed on a part that is an interface of the semiconductor layer (specifically, an interface between the semiconductor layer and a gate insulating film). This makes it possible to suppress generation of a dark current at the part that is the interface of the semiconductor layer (specifically, the interface between the semiconductor layer and the gate insulating layer). Therefore, it is possible to realize a solid-state image sensor that includes a photoelectric converter with a small dark current for each pixel.

In a solid-state image sensor according to a fourth aspect of the present disclosure, a photodiode and a source region and a drain region of a transistor are formed in a semiconductor layer that is a SiGe layer or a Ge layer. Then, a Si layer is formed on a part that is an interface of the semiconductor layer (specifically, an interface between the semiconductor layer and a gate electrode). This makes it possible to suppress generation of a dark current at the part that is the interface of the semiconductor layer (specifically, the interface between the semiconductor layer and the gate electrode). Therefore, it is possible to realize a solid-state image sensor that includes a photoelectric converter with a small dark current for each pixel.

In a ranging system according to a fifth aspect of the present disclosure, a photodiode and a source region and a drain region of a transistor are formed in a semiconductor layer that is a SiGe layer or a Ge layer. Then, a Si layer is formed on a part that is an interface of the semiconductor layer (specifically, an interface between the semiconductor layer and a gate insulating film). This makes it possible to suppress generation of dark current at the part that is the interface of the semiconductor layer (specifically, the interface between the semiconductor layer and the gate insulating layer). Therefore, it is possible to realize a ranging system that includes a photoelectric converter with a small dark current for each pixel.

In a ranging system according to a sixth aspect of the present disclosure, a photodiode and a source region and a drain region of a transistor are formed in a semiconductor layer that is a SiGe layer or a Ge layer. Then, a Si layer is formed on a part that is an interface of the semiconductor layer (specifically, an interface between the semiconductor layer and a gate electrode). This makes it possible to suppress generation of a dark current at the part that is the interface of the semiconductor layer (specifically, the interface between the semiconductor layer and the gate electrode). Therefore, it is possible to realize a ranging system that includes a photoelectric converter having a small dark current for each pixel.

It should be understood by those skilled in the art that various modifications, combinations, sub-combinations and alterations may occur depending on design requirements and other factors insofar as they are within the scope of the appended claims or the equivalents thereof.

1. A photoelectric converter comprising:
a semiconductor layer that is a SiGe layer or a Ge layer;
a photodiode formed in the semiconductor layer;
a transistor having a source region and a drain region in the semiconductor layer and having a gate electrode in contact with the semiconductor layer via a gate insulating film; and
a Si layer formed at an interface between the semiconductor layer and the gate insulating film.

2. The photoelectric converter according to claim 1, wherein:
the Si layer has a thickness equal to or less than a critical film thickness.

3. The photoelectric converter according to claim 1, wherein
the semiconductor layer has a light entering surface and an oxide film covering the light entering surface, and
the Si layer is also formed at an interface between the light entering surface and the oxide film.

4. The photoelectric converter according to claim 1, wherein
the semiconductor layer has an isolation trench formed to surround the transistor,
the photoelectric converter has a filling insulating layer that fills the isolation trench, and
the Si layer is formed at an interface between an inner surface of the isolation trench and the filling insulating layer.

5. The photoelectric converter according to claim 1, wherein
the semiconductor layer has a through hole formed to surround the photodiode,
the photoelectric converter has a filling insulating layer that fills the through hole, and
the Si layer is also formed at an interface between an inner surface of the through hole and the filling insulating layer.

6. A photoelectric converter comprising:
a semiconductor layer that is a SiGe layer or a Ge layer;
a photodiode formed in the semiconductor layer;
a transistor having a source region and a drain region in the semiconductor layer and having a gate electrode extending in the semiconductor layer; and
a Si layer formed at an interface between the semiconductor layer and the gate electrode.

7. The photoelectric converter according to claim 7, wherein
the Si layer has a thickness equal to or less than a critical film thickness.

8. The photoelectric converter according claim 6, wherein
the semiconductor layer has a light entering surface and an oxide film covering the light entering surface, and
the Si layer is also formed at an interface between the light entering surface and the oxide film.

9. The photoelectric converter according to claim 6, wherein
the semiconductor layer has an isolation trench formed to surround the transistor,
the photoelectric converter has a filling insulating layer that fills the isolation trench, and
the Si layer is formed at an interface between an inner surface of the isolation trench and the filling insulating layer.

10. The photoelectric converter according to claim 6, wherein
the semiconductor layer has a through hole formed to surround the photodiode,
the photoelectric converter has a filling insulating layer that fills the through hole, and
the Si layer is formed at an interface between an inner surface of the through hole and the filling insulating layer.

11. A solid-state image sensor comprising:
a photoelectric converter for each pixel, wherein
the photoelectric converter includes:
a semiconductor layer that is a SiGe layer or a Ge layer;
a photodiode formed in the semiconductor layer;
a transistor having a source region and a drain region in the semiconductor layer and having a gate electrode in contact with the semiconductor layer via a gate insulating film; and
a Si layer formed at an interface between the semiconductor layer and the gate insulating film.

12. A solid-state image sensor comprising:
a photoelectric converter for each pixel, wherein
the photoelectric converter includes:
a semiconductor layer that is a SiGe layer or a Ge layer;
a photodiode formed in the semiconductor layer;
a transistor having a source region and a drain region in the semiconductor layer and having a gate electrode extending in the semiconductor layer; and
a Si layer formed at an interface between the semiconductor layer and the gate electrode.

13. A ranging system comprising:
a photoelectric converter for each pixel, wherein
the photoelectric converter includes:
a semiconductor layer that is a SiGe layer or a Ge layer;
a photodiode formed in the semiconductor layer;
a transistor having a source region and a drain region in the semiconductor layer and having a gate electrode in contact with the semiconductor layer via a gate insulating film; and
a Si layer formed at an interface between the semiconductor layer and the gate insulating film.

14. A ranging system comprising:
a photoelectric converter for each pixel, wherein
the photoelectric converter includes:
a semiconductor layer that is a SiGe layer or a Ge layer;
a photodiode formed in the semiconductor layer;
a transistor having a source region and a drain region in the semiconductor layer and having a gate electrode extending in the semiconductor layer; and
a Si layer formed at an interface between the semiconductor layer and the gate electrode.
